(19) United States
(12) Patent Application Publication
(10) Pub. No.: US 2026/0114137 A1
(43) Pub. Date: Apr. 23, 2026

(54) DISPLAY DEVICE

(71) Applicant: YouB LAB Inc., Seongnam-si (KR)

(72) Inventors: Bong Hyun YOU, Seoul (KR); Je In YOU, Seongnam-si (KR)

(21) Appl. No.: 19/428,341

(22) Filed: Dec. 22, 2025

Related U.S. Application Data
(63) Continuation of application No. PCT/KR2024/018167, filed on Nov. 18, 2024.

(30) Foreign Application Priority Data
Jan. 10, 2024 (KR) 10-2024-0004405

(51) Int. Cl. H10K 59/126; H05K 9/00; H10K 59/123; H10K 59/127; H10K 59/80

(52) U.S. Cl. CPC H10K 59/126; H05K 9/0079; H05K 9/0083; H10K 59/123; H10K 59/127; H10K 59/8794

(57) ABSTRACT

A display device includes a metal layer, a multi-functional layer, an adhesive layer, a display substrate, a printed circuit board, and a conductive connector. The multi-functional layer is disposed on the metal layer, and includes graphite and a resin mixed with the graphite. The adhesive layer is disposed on the multi-functional layer. The display substrate is disposed on the adhesive layer. The conductive connector directly connects a first surface of the printed circuit board and a lower surface of the metal layer.

### CROSS-REFERENCE TO RELATED APPLICATION

This application is a bypass continuation application of International Patent Application No. PCT/KR2024/018167, filed on Nov. 18, 2024, which is based on and claims the benefit of priority to Korean Patent Application No. 10-2024-0004405, filed Jan. 10, 2024, the disclosures of which are hereby incorporated by reference in their entireties.

### TECHNICAL FIELD

The present disclosure relates to a display device, and more particularly, to a display device including a multi-functional member that performs heat dissipation, electromagnetic interference (EMI) shielding, and electrostatic discharge (ESD) shielding.

### BACKGROUND

Generally, a display device includes a display panel and a display panel driver. The display panel displays an image based on an input image, and includes a plurality of gate lines, a plurality of data lines, and a plurality of pixels. The display panel driver includes a gate driver providing gate signals to the plurality of gate lines, a data driver providing data voltages to the data lines, and a driving controller controlling operations of the gate driver and the data driver.

The display device may generate heat during operation. If the display device does not properly dissipate heat, the display device may overheat and be damaged. Generally, in the case of an OLED self-emissive display, a current for light emission is transmitted to an organic EL diode, and heat is generated. Such heat causes deterioration such as Burn In of an EL material, thereby degrading image quality. Also, when such heat generated from a front surface of the display comes into contact with a human body, it may cause injury to the human body such as a burn.

Also, the display device may generate electromagnetic waves during operation. If the electromagnetic waves are not properly shielded and a user is exposed to the electromagnetic waves for a long time, there is a concern that health problems of the user may occur. Also, the display device may generate static electricity during operation. If the static electricity is not properly shielded, the display device may malfunction or be damaged.

### SUMMARY

Accordingly, a technical object of the present disclosure is derived from these points, and an object of the present disclosure is to provide a display device including a multi-functional member that performs heat dissipation, electromagnetic interference (EMI) shielding, electrostatic discharge (ESD) shielding, light shielding of rear reflected light, and absorption of an impact introduced from the outside of the display device.

A display device according to an embodiment for realizing the object of the present invention described above includes a metal layer, a multi-functional layer, an adhesive layer, a display substrate, a printed circuit board, and a conductive connector. The multi-functional layer is disposed on the metal layer, and includes graphite and a resin mixed with the graphite. The adhesive layer is disposed on the multi-functional layer. The display substrate is disposed on the adhesive layer. The conductive connector directly connects a first surface of the printed circuit board and a lower surface of the metal layer.

In an embodiment of the present invention, a mass ratio of the graphite in the multi-functional layer may be 30 wt % to 90 wt %, and a mass ratio of the resin in the multi-functional layer may be 70 wt % to 10 wt %. In an embodiment of the present invention, in a cross-sectional view, a width of the multi-functional layer may be equal to a width of the adhesive layer. In an embodiment of the present invention, the multi-functional layer may be an anisotropic heat dissipation member, and the metal layer may be an isotropic heat dissipation member. In an embodiment of the present invention, the multi-functional layer and the metal layer may be in direct contact.

In an embodiment of the present invention, the display device may further include a first anisotropic conductive film disposed on the display substrate, a second anisotropic conductive film disposed on a second surface of the printed circuit board, and a flexible film contacting the first anisotropic conductive film and the second anisotropic conductive film. In an embodiment of the present invention, the display device may further include a first driving circuit disposed on the flexible film and a second driving circuit disposed on the second surface of the printed circuit board.

In an embodiment of the present invention, in a cross-sectional view, a width of the conductive connector may be equal to a width of the printed circuit board. In an embodiment of the present invention, in a cross-sectional view, a width of the conductive connector may be smaller than a width of the printed circuit board. In an embodiment of the present invention, the conductive connector may be integrally formed with the metal layer. In an embodiment of the present invention, the conductive connector may be a pin of the printed circuit board protruding from the printed circuit board.

In an embodiment of the present invention, the display device may further include a metal electrode contacting the lower surface of the metal layer. In an embodiment of the present invention, the metal electrode may be connected to a ground. In an embodiment of the present invention, the metal electrode may be connected to a power voltage line of the display device. In an embodiment of the present invention, the display device may further include an insulating layer disposed between the multi-functional layer and the metal layer.

In an embodiment of the present invention, the display device may further include a second display substrate disposed on the display substrate. In a cross-sectional view, a width of the display substrate may be greater than a width of the second display substrate. In an embodiment of the present invention, the multi-functional layer may include graphite powder of a first size and graphite powder of a second size smaller than the first size. In an embodiment of the present invention, the graphite powder of the first size may be 60 μm or more and 100 μm or less. The graphite powder of the second size may be 4 μm or more and 40 μm or less.

A display device according to an embodiment for realizing the object of the present invention described above includes a metal layer, a multi-functional layer, an adhesive layer, and a display substrate. The multi-functional layer contacts the metal layer, and includes graphite and a resin mixed with the graphite. The adhesive layer is disposed on the metal layer and the multi-functional layer. The display substrate is disposed on the adhesive layer.

A display device according to an embodiment for realizing the object of the present invention described above includes a metal layer, a multi-functional layer, an adhesive layer, and a display substrate. The multi-functional layer contacts the metal layer, and includes a heat dissipation material including at least one of graphite, graphene, carbon fiber, carbon nanotube, boron nitride, and alumina, and a resin mixed with the heat dissipation material. The adhesive layer is disposed on the metal layer and the multi-functional layer. The display substrate is disposed on the adhesive layer.

According to such a display device, the display device includes a metal layer and a multi-functional layer contacting the metal layer and including graphite and a resin mixed with the graphite, and the multi-functional layer can be adhered to the display substrate through an adhesive layer.

Heat dissipation, electromagnetic interference (EMI) shielding, and electrostatic discharge (ESD) shielding are performed by the metal layer and the multi-functional layer, so that damage to the display device is prevented, and safety and reliability of the display device can be improved.

Since the multi-functional layer, which is an anisotropic heat dissipation member, and the metal layer, which is an isotropic heat dissipation member, are in direct contact, the heat dissipation function can be further improved.

In addition, blocking of rear reflected light can be performed by the multi-functional layer, impact can be absorbed by the multi-functional layer, rigidity can be increased by the metal layer, and adhesiveness can be improved by the adhesive layer.

Also, since the multi-functional layer includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member can be improved.

### BRIEF DESCRIPTION OF THE DRAWINGS

Embodiments will be more clearly understood from the following detailed description taken in conjunction with the accompanying drawings in which:

FIG. 1 is a block diagram illustrating a display device according to an embodiment of the present invention.

FIG. 2 is a cross-sectional view illustrating the display device of FIG. 1.

FIG. 3 is a cross-sectional view illustrating a display device according to an embodiment of the present invention.

FIG. 4 is a cross-sectional view illustrating a display device according to an embodiment of the present invention.

FIG. 5 is a cross-sectional view illustrating a display device according to an embodiment of the present invention.

FIG. 6 is a cross-sectional view illustrating a display device according to an embodiment of the present invention.

FIG. 7 is a cross-sectional view illustrating a display device according to an embodiment of the present invention.

FIG. 8 is a block diagram illustrating an electronic device according to an embodiment of the present invention.

FIG. 9 is a diagram illustrating an example in which the electronic device of FIG. 8 is implemented as a smartphone.

FIG. 10 is a diagram illustrating an example in which the electronic device of FIG. 8 is implemented as a monitor.

### DETAILED DESCRIPTION

Embodiments of the present disclosure described herein are illustrated for the purpose of explaining the embodiments of the present disclosure, and the embodiments of the present disclosure may be implemented in various forms and should not be construed as limited to the embodiments set forth herein.

The present disclosure may be variously modified and may have various forms, and specific embodiments will be illustrated in the drawings and described in detail in the text.

However, this is not intended to limit the present disclosure to a specific disclosure form, and should be understood to include all modifications, equivalents, and substitutes included in the spirit and technical scope of the present disclosure.

Terms such as first, second, etc. may be used to describe various components, but the components should not be limited by the terms. The terms may be used for the purpose of distinguishing one component from another component. For example, without departing from the scope of the present disclosure, a first component may be referred to as a second component, and similarly, a second component may be referred to as a first component.

When a component is referred to as being “connected” or “coupled” to another component, it should be understood that it may be directly connected or coupled to the other component, but other components may exist therebetween. On the other hand, when a component is referred to as being “directly connected” or “directly coupled” to another component, it should be understood that no other component exists therebetween. Other expressions describing the relationship between components, such as “between” and “directly between” or “adjacent to” and “directly adjacent to,”should be interpreted similarly.

The terminology used herein is for the purpose of describing particular embodiments only and is not intended to be limiting of the present disclosure. Singular expressions include plural expressions unless the context clearly indicates otherwise. In the present application, terms such as “comprise,” “include,” or “have” are intended to designate that a feature, number, step, operation, component, part, or combination thereof described in the disclosure exists, but it should be understood that the existence or addition possibility of one or more other features, numbers, steps, operations, components, parts, or combinations thereof is not precluded in advance.

Unless otherwise defined, all terms used herein, including technical or scientific terms, have the same meaning as generally understood by those skilled in the art to which the present disclosure pertains. Terms such as those defined in generally used dictionaries should be interpreted as having meanings consistent with the meanings in the context of the related art, and are not interpreted in an ideal or excessively formal sense unless explicitly defined in the present application.

Meanwhile, when an embodiment can be implemented differently, a specific function or operation specified in a specific block may occur differently from the order specified in the flowchart. For example, two continuous blocks may actually be performed substantially simultaneously, or the blocks may be performed in reverse order depending on the related function or operation.

Hereinafter, preferred embodiments of the present disclosure will be described in more detail with reference to the accompanying drawings. The same reference numerals are used for the same components in the drawings, and duplicate descriptions of the same components are omitted.

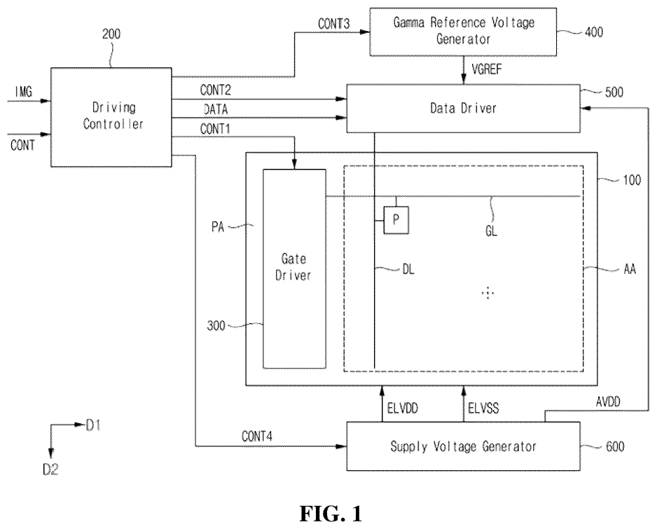

FIG. 1 is a block diagram illustrating a display device according to an embodiment of the present invention.

Referring to FIG. 1, the display device includes a display panel 100 and a display panel driver. The display panel driver drives the display panel 100. The display panel driver includes a driving controller 200, a gate driver 300, a gamma reference voltage generator 400, and a data driver 500. The display panel driver may further include a power voltage generator 600.

For example, the driving controller 200 and the data driver 500 may be integrally formed. For example, the driving controller 200, the gamma reference voltage generator 400, and the data driver 500 may be integrally formed. A driving module in which at least the driving controller 200 and the data driver 500 are integrally formed may be named a Timing Controller Embedded Data Driver (TED).

The display panel 100 includes a display area AA displaying an image and a peripheral area PA disposed adjacent to the display area AA.

The display panel 100 includes a plurality of gate lines GL, a plurality of data lines DL, and a plurality of pixels P electrically connected to the gate lines GL and the data lines DL, respectively. The gate lines GL may extend in a first direction D1, and the data lines DL may extend in a second direction D2 crossing the first direction D1.

The driving controller 200 receives input image data IMG and an input control signal CONT from an external device (e.g., an application processor). For example, the input image data IMG may include red image data, green image data, and blue image data. The input image data IMG may include white image data. The input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 200 may generate a first control signal CONT1, a second control signal CONT2, a third control signal CONT3, a fourth control signal CONT4, and a data signal DATA based on the input image data IMG and the input control signal CONT.

The driving controller 200 may generate the first control signal CONT1 for controlling an operation of the gate driver 300 based on the input control signal CONT and output it to the gate driver 300. The first control signal CONT1 may include a vertical start signal and a gate clock signal.

The driving controller 200 may generate the second control signal CONT2 for controlling an operation of the data driver 500 based on the input control signal CONT and output it to the data driver 500. The second control signal CONT2 may include a horizontal start signal and a load signal.

The driving controller 200 generates the data signal DATA based on the input image data IMG. The driving controller 200 outputs the data signal DATA to the data driver 500.

The driving controller 200 may generate the third control signal CONT3 for controlling an operation of the gamma reference voltage generator 400 based on the input control signal CONT and output it to the gamma reference voltage generator 400.

The gate driver 300 may generate gate signals for driving the gate lines GL in response to the first control signal CONT1 input from the driving controller 200. The gate driver 300 may output the gate signals to the gate lines GL. For example, the gate driver 300 may sequentially output the gate signals to the gate lines GL. For example, the gate driver 300 may be mounted on the peripheral area PA of the display panel 100. For example, the gate driver 300 may be integrated on the peripheral area PA of the display panel 100.

The gamma reference voltage generator 400 may generate a gamma reference voltage VGREF in response to the third control signal CONT3 input from the driving controller 200. The gamma reference voltage generator 400 may provide the gamma reference voltage VGREF to the data driver 500.

In an embodiment of the present invention, the gamma reference voltage generator 400 may be disposed within the driving controller 200 or disposed within the data driver 500.

The data driver 500 may receive the second control signal CONT2 and the data signal DATA from the driving controller 200, and receive the gamma reference voltage VGREF from the gamma reference voltage generator 400. The data driver 500 may convert the data signal DATA into a data voltage of an analog form using the gamma reference voltage VGREF. The data driver 500 may output the data voltage to the data line DL.

The power voltage generator 600 may generate a power voltage in response to the fourth control signal CONT4 input from the driving controller 200. For example, the power voltage generator 600 may generate a first power voltage ELVDD and a second power voltage ELVSS applied to the pixel P of the display panel 100. For example, the power voltage generator 600 may generate a data power voltage AVDD applied to the data driver 500.

FIG. 2 is a cross-sectional view illustrating the display device of FIG. 1.

Referring to FIGS. 1 and 2, the display device includes a metal layer ML, a multi-functional layer TF, an adhesive layer TA, and a display substrate S1. Here, the metal layer ML, the multi-functional layer TF, and the adhesive layer TA may be referred to as a multi-functional member MFE.

The metal layer ML may include at least one of copper and aluminum.

The multi-functional layer TF may contact the metal layer ML. The multi-functional layer TF may include a heat dissipation material including at least one of graphite, graphene, carbon fiber, carbon nanotube, boron nitride, and alumina, and a resin mixed with the heat dissipation material. The resin may include at least one of polyurethane (PU), thermosetting polyurethane (TPU), silicone, epoxy, acryl, and rubber.

For example, the multi-functional layer TF may include the graphite and a resin mixed with the graphite. For example, the multi-functional layer TF may include graphite powder and the resin mixed with the graphite powder. That is, the graphite powder may be mixed with the resin and formed on the metal layer ML. The resin may be a binder resin.

Here, a mass ratio of the graphite in the multi-functional layer TF may be 30 wt % to 90 wt %. A mass ratio of the resin in the multi-functional layer TF may be 70 wt % to 10 wt %. That is, when the graphite in the multi-functional layer TF is 30 wt %, the resin may be 70 wt %, and when the graphite in the multi-functional layer TF is 90 wt %, the resin may be 10 wt %.

For example, a size of the graphite powder may be 1 μm or more and 100 μm or less. The size of the graphite powder may be 4 μm or more and 40 μm or less.

For example, the multi-functional layer TF may include graphite powder of a first size and graphite powder of a second size smaller than the first size. For example, the graphite powder of the first size may be 60 μm or more and 100 μm or less. For example, the graphite powder of the second size may be 4 μm or more and 40 μm or less. The first size and the second size may mean sizes in a state of being mixed with the resin and disposed in the display device. The powder of the first size and the powder of the second size may have sizes larger than the first size and the second size, respectively, before being mixed with the resin.

When dispersing the graphite powder in the binder resin, an appropriate dispersion method and defoaming method may be used so that powder particles can be evenly distributed in a dispersion liquid without bubbles.

Mixing of the graphite and the binder resin may be performed without a solvent or may be performed using a solvent according to a mixing ratio. When mixing using a solvent, a solvent that less affects dispersion and defoaming (bubble removal) may be selected among solvents such as water, alcohol, acetate, etc., and a layer of the graphite and the binder resin can be made by an appropriate curing method (temperature, Aging, etc.) so that pores are not generated as the solvent evaporates during curing.

The adhesive layer TA is disposed on the metal layer ML and the multi-functional layer TF. For example, as shown in FIG. 2, the multi-functional layer TF may be disposed on the metal layer ML, and the adhesive layer TA may be disposed on the multi-functional layer TF.

The display device further includes a printed circuit board PCB and a conductive connector CT. The conductive connector CT may directly connect a first surface of the printed circuit board PCB and a lower surface of the metal layer ML.

The multi-functional layer TF may be an anisotropic heat dissipation member, and the metal layer ML may be an isotropic heat dissipation member. In the present embodiment, the multi-functional layer TF and the metal layer may be in direct contact. Since the multi-functional layer TF, which is an anisotropic heat dissipation member, and the metal layer ML, which is an isotropic heat dissipation member, are in direct contact, the heat dissipation function can be further improved.

The display device may further include a first anisotropic conductive film ACF1 disposed on the display substrate S1, a second anisotropic conductive film ACF2 disposed on a second surface of the printed circuit board PCB, and a flexible film FF contacting the first anisotropic conductive film ACF1 and the second anisotropic conductive film ACF2.

The display device may further include a first driving circuit CC1 disposed on the flexible film FF and a second driving circuit CC2 disposed on the second surface of the printed circuit board PCB.

For example, the first driving circuit CC1 may include the data driver 500. For example, the first driving circuit CC1 may include a Timing Controller Embedded Data Driver (TED) in which the driving controller 200 and the data driver 500 are integrally formed.

For example, the second driving circuit CC2 may include the driving controller 200. For example, the second driving circuit CC2 may include the power voltage generator 600.

In the present embodiment, in a cross-sectional view, a width of the conductive connector CT may be equal to a width of the printed circuit board PCB. For example, the conductive connector CT may be a thermally conductive adhesive.

The display device may further include a second display substrate S2 disposed on the display substrate S1. The display substrate S1 may be a lower substrate of the display device, and the second display substrate S2 may be an upper substrate of the display device.

In a cross-sectional view, a width of the display substrate S1 may be greater than a width of the second display substrate S2. The first anisotropic conductive film ACF1 may be disposed in an area of the display substrate S1 that does not overlap with the second display substrate S2.

The multi-functional member MFE includes the metal layer ML which is an isotropic material and the multi-functional layer TF which is an anisotropic material, thereby efficiently spreading heat generated in the display device to remove a hot spot in a specific portion of the display device and lower the overall heat (temperature).

The multi-functional member MFE includes the multi-functional layer TF and is connected to the printed circuit board PCB by the conductive connector CT, thereby diffusing heat generated in the second driving circuit CC2.

The multi-functional member MFE includes the metal layer ML and is connected to the printed circuit board PCB by the conductive connector CT, thereby quickly dissipating static electricity on the printed circuit board PCB or static electricity transferred through a surface of the display panel 100 using conduction of the metal layer ML.

A material having high conductivity (very low resistance) may have an electromagnetic wave shielding function. The multi-functional member MFE includes the metal layer ML which is an isotropic material and the multi-functional layer TF which is an anisotropic material, thereby having high conductivity to perform an electromagnetic wave shielding function.

The multi-functional member MFE includes the metal layer ML and is connected to the printed circuit board PCB by the conductive connector CT, thereby effectively shielding electromagnetic waves radiated from the first driving circuit CC1 and the second driving circuit CC2. Since the metal layer ML has a large area, the electromagnetic waves can be effectively shielded.

Since the graphite of the multi-functional layer TF has a dark gray color, it can serve as a light blocking role to prevent light leakage in the display area of the display panel 100.

Since the graphite of the multi-functional layer TF has a more elastic property than metal, it can perform a shock absorption function and prevent the display substrate S1 from breaking.

Since the multi-functional layer TF includes the graphite and the resin mixed with the graphite, the possibility that particles of the graphite fall off or smear out is low, and accordingly, a sealing process of the graphite is not required.

Since a space for sealing the graphite is not required, in the cross-sectional view of FIG. 2, the width of the multi-functional layer TF may be equal to the width of the adhesive layer TA.

Since a space for sealing the graphite is not required, heat dissipation efficiency of the multi-functional member MFE can be improved.

According to the present embodiment, the display device includes the metal layer ML and the multi-functional layer TF contacting the metal layer ML and including graphite and a resin mixed with the graphite, and the multi-functional layer TF can be adhered to the display substrate S1 through the adhesive layer TA.

Heat dissipation, electromagnetic interference (EMI) shielding, and electrostatic discharge (ESD) shielding are performed by the metal layer ML and the multi-functional layer TF, so that damage to the display device is prevented, and safety and reliability of the display device can be improved.

Since the multi-functional layer TF, which is an anisotropic heat dissipation member, and the metal layer ML, which is an isotropic heat dissipation member, are in direct contact, the heat dissipation function can be further improved.

In addition, blocking of rear reflected light can be performed by the multi-functional layer TF, impact can be absorbed by the multi-functional layer TF, rigidity can be increased by the metal layer ML, and adhesiveness can be improved by the adhesive layer TA.

Also, since the multi-functional layer TF includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member MFE can be improved.

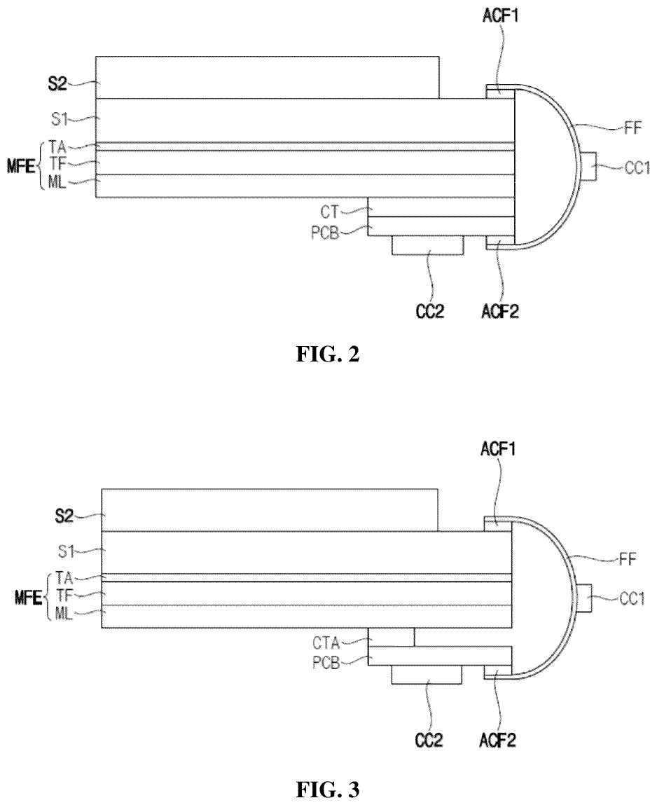

FIG. 3 is a cross-sectional view illustrating a display device according to an embodiment of the present invention.

Since the display device according to the present embodiment is substantially the same as the display device of FIGS. 1 and 2 except for a conductive connector, the same reference numerals are used for the same or similar components, and redundant descriptions are omitted.

Referring to FIGS. 1 and 3, the display device includes a metal layer ML, a multi-functional layer TF, an adhesive layer TA, and a display substrate S1. Here, the metal layer ML, the multi-functional layer TF, and the adhesive layer TA may be referred to as a multi-functional member MFE.

The multi-functional layer TF may contact the metal layer ML. The multi-functional layer TF may include a heat dissipation material including at least one of graphite, graphene, carbon nanotube, boron nitride, and alumina, and a resin mixed with the heat dissipation material. The resin may include at least one of epoxy and acryl.

For example, the multi-functional layer TF may include the graphite and a resin mixed with the graphite. For example, the multi-functional layer TF may include graphite powder and the resin mixed with the graphite powder. That is, the graphite powder may be mixed with the resin and formed on the metal layer ML.

The display device further includes a printed circuit board PCB and a conductive connector CTA. The conductive connector CTA may directly connect a first surface of the printed circuit board PCB and a lower surface of the metal layer ML.

In the present embodiment, in a cross-sectional view, a width of the conductive connector CTA may be smaller than a width of the printed circuit board PCB. For example, the conductive connector CTA may be a thermally conductive adhesive or a conductive material.

According to the present embodiment, the display device includes the metal layer ML and the multi-functional layer TF contacting the metal layer ML and including graphite and a resin mixed with the graphite, and the multi-functional layer TF can be adhered to the display substrate S1 through the adhesive layer TA.

Heat dissipation, electromagnetic interference (EMI) shielding, and electrostatic discharge (ESD) shielding are performed by the metal layer ML and the multi-functional layer TF, so that damage to the display device is prevented, and safety and reliability of the display device can be improved.

Since the multi-functional layer TF, which is an anisotropic heat dissipation member, and the metal layer ML, which is an isotropic heat dissipation member, are in direct contact, the heat dissipation function can be further improved.

In addition, blocking of rear reflected light can be performed by the multi-functional layer TF, impact can be absorbed by the multi-functional layer TF, rigidity can be increased by the metal layer ML, and adhesiveness can be improved by the adhesive layer TA.

Also, since the multi-functional layer TF includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member MFE can be improved.

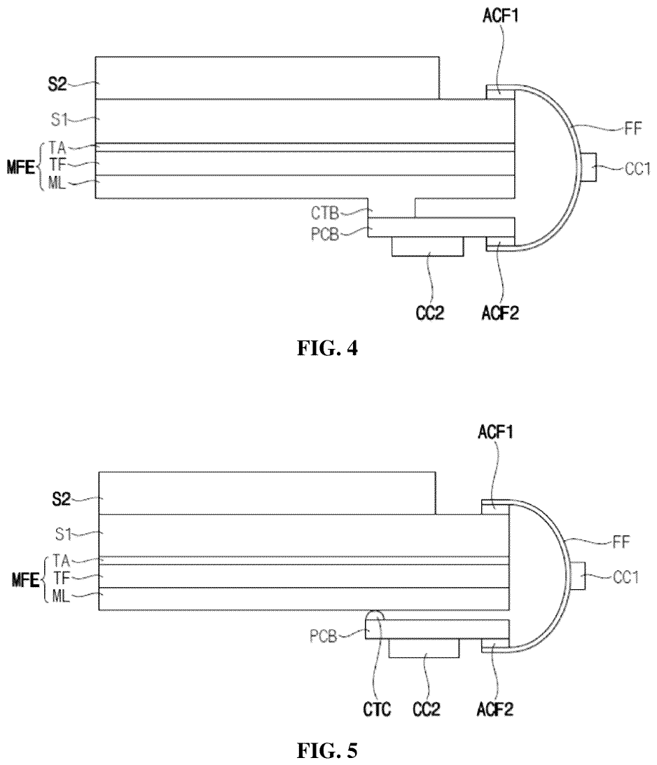

FIG. 4 is a cross-sectional view illustrating a display device according to an embodiment of the present invention.

Since the display device according to the present embodiment is substantially the same as the display device of FIGS. 1 and 2 except for a conductive connector, the same reference numerals are used for the same or similar components, and redundant descriptions are omitted.

Referring to FIGS. 1 and 4, the display device includes a metal layer ML, a multi-functional layer TF, an adhesive layer TA, and a display substrate S1. Here, the metal layer ML, the multi-functional layer TF, and the adhesive layer TA may be referred to as a multi-functional member MFE.

The multi-functional layer TF may contact the metal layer ML. The multi-functional layer TF may include a heat dissipation material including at least one of graphite, graphene, carbon nanotube, boron nitride, and alumina, and a resin mixed with the heat dissipation material. The resin may include at least one of epoxy and acryl.

For example, the multi-functional layer TF may include the graphite and a resin mixed with the graphite. For example, the multi-functional layer TF may include graphite powder and the resin mixed with the graphite powder. That is, the graphite powder may be mixed with the resin and formed on the metal layer ML.

The display device further includes a printed circuit board PCB and a conductive connector CTB. The conductive connector CTB may directly connect a first surface of the printed circuit board PCB and a lower surface of the metal layer ML.

In the present embodiment, in a cross-sectional view, a width of the conductive connector CTB may be smaller than a width of the printed circuit board PCB. In the present embodiment, the conductive connector CTB may be integrally formed with the metal layer ML. That is, the conductive connector CTB may be a protrusion of the metal layer ML.

According to the present embodiment, the display device includes the metal layer ML and the multi-functional layer TF contacting the metal layer ML and including graphite and a resin mixed with the graphite, and the multi-functional layer TF can be adhered to the display substrate S1 through the adhesive layer TA.

Heat dissipation, electromagnetic interference (EMI) shielding, and electrostatic discharge (ESD) shielding are performed by the metal layer ML and the multi-functional layer TF, so that damage to the display device is prevented, and safety and reliability of the display device can be improved.

Since the multi-functional layer TF, which is an anisotropic heat dissipation member, and the metal layer ML, which is an isotropic heat dissipation member, are in direct contact, the heat dissipation function can be further improved.

In addition, blocking of rear reflected light can be performed by the multi-functional layer TF, impact can be absorbed by the multi-functional layer TF, rigidity can be increased by the metal layer ML, and adhesiveness can be improved by the adhesive layer TA.

Also, since the multi-functional layer TF includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member MFE can be improved.

FIG. 5 is a cross-sectional view illustrating a display device according to an embodiment of the present invention.

Since the display device according to the present embodiment is substantially the same as the display device of FIGS. 1 and 2 except for a conductive connector, the same reference numerals are used for the same or similar components, and redundant descriptions are omitted.

Referring to FIGS. 1 and 5, the display device includes a metal layer ML, a multi-functional layer TF, an adhesive layer TA, and a display substrate S1. Here, the metal layer ML, the multi-functional layer TF, and the adhesive layer TA may be referred to as a multi-functional member MFE.

The multi-functional layer TF may contact the metal layer ML. The multi-functional layer TF may include a heat dissipation material including at least one of graphite, graphene, carbon nanotube, boron nitride, and alumina, and a resin mixed with the heat dissipation material. The resin may include at least one of epoxy and acryl.

For example, the multi-functional layer TF may include the graphite and a resin mixed with the graphite. For example, the multi-functional layer TF may include graphite powder and the resin mixed with the graphite powder. That is, the graphite powder may be mixed with the resin and formed on the metal layer ML.

The display device further includes a printed circuit board PCB and a conductive connector CTC. The conductive connector CTC may directly connect a first surface of the printed circuit board PCB and a lower surface of the metal layer ML.

In the present embodiment, in a cross-sectional view, a width of the conductive connector CTC may be smaller than a width of the printed circuit board PCB. In the present embodiment, the conductive connector CTC may protrude from the printed circuit board PCB. For example, the conductive connector CTC may be a pin of the printed circuit board PCB protruding from the printed circuit board PCB.

According to the present embodiment, the display device includes the metal layer ML and the multi-functional layer TF contacting the metal layer ML and including graphite and a resin mixed with the graphite, and the multi-functional layer TF can be adhered to the display substrate S1 through the adhesive layer TA.

Heat dissipation, electromagnetic interference (EMI) shielding, and electrostatic discharge (ESD) shielding are performed by the metal layer ML and the multi-functional layer TF, so that damage to the display device is prevented, and safety and reliability of the display device can be improved.

Since the multi-functional layer TF, which is an anisotropic heat dissipation member, and the metal layer ML, which is an isotropic heat dissipation member, are in direct contact, the heat dissipation function can be further improved.

In addition, blocking of rear reflected light can be performed by the multi-functional layer TF, impact can be absorbed by the multi-functional layer TF, rigidity can be increased by the metal layer ML, and adhesiveness can be improved by the adhesive layer TA.

Also, since the multi-functional layer TF includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member MFE can be improved.

FIG. 6 is a cross-sectional view illustrating a display device according to an embodiment of the present invention.

Since the display device according to the present embodiment is substantially the same as the display device of FIGS. 1 and 2 except that it further includes a metal electrode, the same reference numerals are used for the same or similar components, and redundant descriptions are omitted.

Referring to FIGS. 1 and 6, the display device includes a metal layer ML, a multi-functional layer TF, an adhesive layer TA, and a display substrate S1. Here, the metal layer ML, the multi-functional layer TF, and the adhesive layer TA may be referred to as a multi-functional member MFE.

The multi-functional layer TF may contact the metal layer ML. The multi-functional layer TF may include a heat dissipation material including at least one of graphite, graphene, carbon nanotube, boron nitride, and alumina, and a resin mixed with the heat dissipation material. The resin may include at least one of epoxy and acryl.

For example, the multi-functional layer TF may include the graphite and a resin mixed with the graphite. For example, the multi-functional layer TF may include graphite powder and the resin mixed with the graphite powder. That is, the graphite powder may be mixed with the resin and formed on the metal layer ML.

The display device further includes a printed circuit board PCB and a conductive connector CT. The conductive connector CT may directly connect a first surface of the printed circuit board PCB and a lower surface of the metal layer ML.

In the present embodiment, the display device may further include a metal electrode ME contacting the lower surface of the metal layer ML. For example, the metal electrode ME may be connected to a ground. Alternatively, the metal electrode ME may be connected to a power voltage line of the display device.

Since a static electricity path and an electromagnetic wave path are formed by the printed circuit board PCB, the conductive connector CT, the metal layer ML, and the metal electrode ME, electrostatic shielding performance and electromagnetic wave shielding performance can be improved by the metal electrode ME.

According to the present embodiment, the display device includes the metal layer ML and the multi-functional layer TF contacting the metal layer ML and including graphite and a resin mixed with the graphite, and the multi-functional layer TF can be adhered to the display substrate S1 through the adhesive layer TA.

Heat dissipation, electromagnetic interference (EMI) shielding, and electrostatic discharge (ESD) shielding are performed by the metal layer ML and the multi-functional layer TF, so that damage to the display device is prevented, and safety and reliability of the display device can be improved.

Since the multi-functional layer TF, which is an anisotropic heat dissipation member, and the metal layer ML, which is an isotropic heat dissipation member, are in direct contact, the heat dissipation function can be further improved.

In addition, blocking of rear reflected light can be performed by the multi-functional layer TF, impact can be absorbed by the multi-functional layer TF, rigidity can be increased by the metal layer ML, and adhesiveness can be improved by the adhesive layer TA.

Also, since the multi-functional layer TF includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member MFE can be improved.

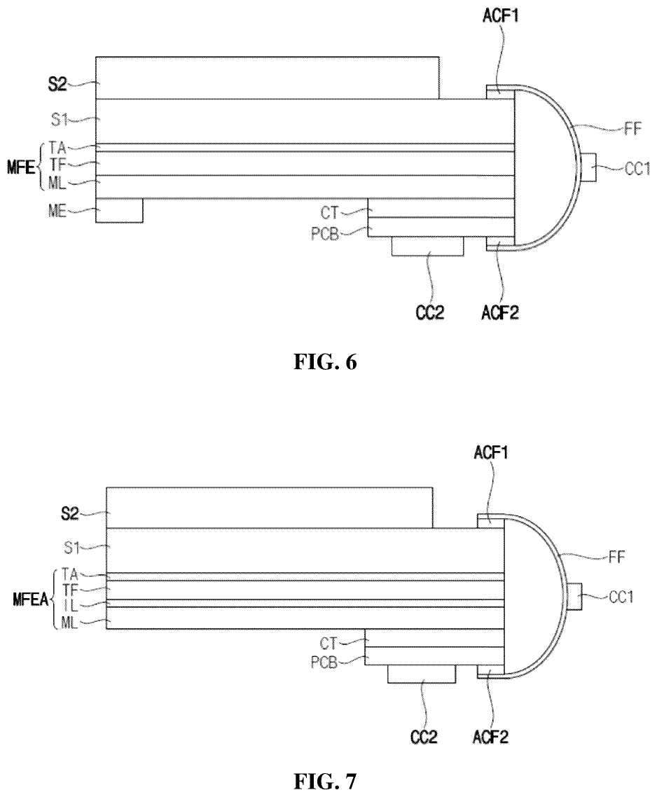

FIG. 7 is a cross-sectional view illustrating a display device according to an embodiment of the present invention.

Since the display device according to the present embodiment is substantially the same as the display device of FIGS. 1 and 2 except that it further includes an insulating layer, the same reference numerals are used for the same or similar components, and redundant descriptions are omitted.

Referring to FIGS. 1 and 7, the display device includes a metal layer ML, a multi-functional layer TF, an adhesive layer TA, and a display substrate S1. Here, the metal layer ML, the multi-functional layer TF, and the adhesive layer TA may be referred to as a multi-functional member MFEA.

The multi-functional layer TF may contact the metal layer ML. The multi-functional layer TF may include a heat dissipation material including at least one of graphite, graphene, carbon nanotube, boron nitride, and alumina, and a resin mixed with the heat dissipation material. The resin may include at least one of epoxy and acryl.

For example, the multi-functional layer TF may include the graphite and a resin mixed with the graphite. For example, the multi-functional layer TF may include graphite powder and the resin mixed with the graphite powder. That is, the graphite powder may be mixed with the resin and formed on the metal layer ML.

The display device further includes a printed circuit board PCB and a conductive connector CT. The conductive connector CT may directly connect a first surface of the printed circuit board PCB and a lower surface of the metal layer ML.

In the present embodiment, the display device may further include an insulating layer IL disposed between the multi-functional layer TF and the metal layer ML.

For example, the insulating layer IL may be a double-sided adhesive layer. For example, the insulating layer IL may include at least one of polyethylene terephthalate (PET), polycarbonate (PC), polytetrafluoroethylene (PTFE), polyurethane (PU), thermoplastic polyurethane (TPU), aerogel, and mica.

According to the present embodiment, the display device includes the metal layer ML and the multi-functional layer TF contacting the metal layer ML and including graphite and a resin mixed with the graphite, and the multi-functional layer TF can be adhered to the display substrate S1 through the adhesive layer TA.

Heat dissipation, electromagnetic interference (EMI) shielding, and electrostatic discharge (ESD) shielding are performed by the metal layer ML and the multi-functional layer TF, so that damage to the display device is prevented, and safety and reliability of the display device can be improved.

Since the multi-functional layer TF, which is an anisotropic heat dissipation member, and the metal layer ML, which is an isotropic heat dissipation member, are in direct contact, the heat dissipation function can be further improved.

In addition, blocking of rear reflected light can be performed by the multi-functional layer TF, impact can be absorbed by the multi-functional layer TF, rigidity can be increased by the metal layer ML, and adhesiveness can be improved by the adhesive layer TA.

Also, since the multi-functional layer TF includes the graphite and the resin mixed with the graphite, particles of the graphite do not fall off or smear out, and a sealing process of the graphite is not required. Accordingly, a manufacturing process of the display device can be simplified, a dead space of the display device can be reduced, and heat dissipation efficiency of the multi-functional member MFEA can be improved.

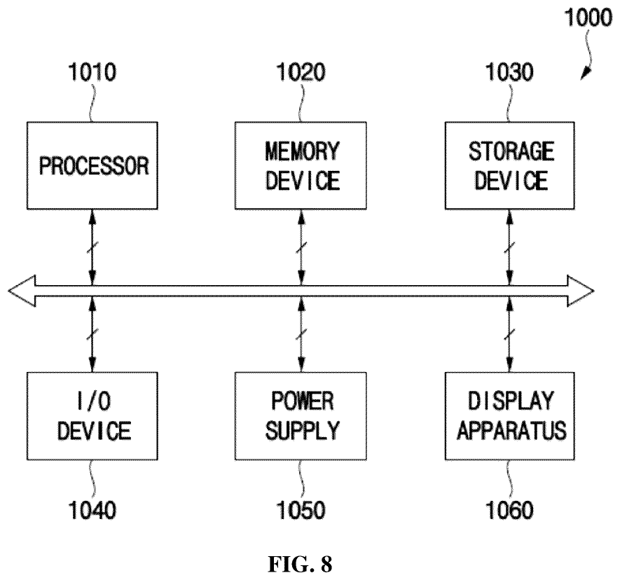

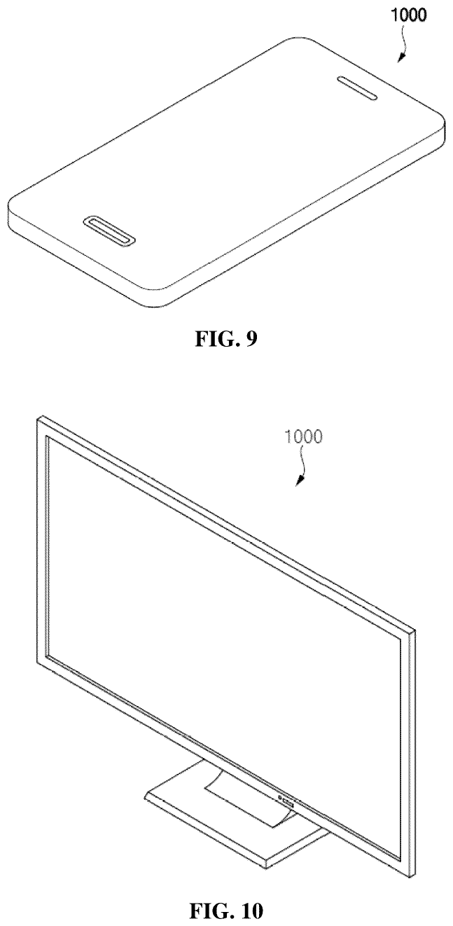

FIG. 8 is a block diagram illustrating an electronic device according to an embodiment of the present invention. FIG. 9 is a diagram illustrating an example in which the electronic device of FIG. 8 is implemented as a smartphone. FIG. 10 is a diagram illustrating an example in which the electronic device of FIG. 8 is implemented as a monitor.

Referring to FIGS. 8 to 10, the electronic device 1000 may include a processor 1010, a memory device 1020, a storage device 1030, an input/output device 1040, a power supply 1050, and a display device 1060. Here, the display device 1060 may be the display device of FIG. 1. Also, the electronic device 1000 may further include various ports capable of communicating with a video card, a sound card, a memory card, a USB device, etc., or communicating with other systems.

According to an embodiment, as shown in FIG. 9, the electronic device 1000 may be implemented as a smartphone. As shown in FIG. 10, the electronic device 1000 may be implemented as a monitor. However, this is exemplary, and the electronic device 1000 is not limited thereto. For example, the electronic device 1000 may be implemented as a television, a mobile phone, a video phone, a smart pad, a smart watch, a tablet PC, a vehicle navigation system, a laptop, a head-mounted display device, etc.

The processor 1010 may perform specific calculations or tasks. According to an embodiment, the processor 1010 may be a microprocessor, a central processing unit, an application processor, etc. The processor 1010 may be connected to other components through an address bus, a control bus, and a data bus, etc. According to an embodiment, the processor 1010 may also be connected to an expansion bus such as a Peripheral Component Interconnect (PCI) bus.

The processor 1010 may output the input image data IMG and the input control signal CONT to the driving controller 200 of FIG. 1.

The memory device 1020 may store data necessary for the operation of the electronic device 1000. For example, the memory device 1020 may include a non-volatile memory device such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM), a Ferroelectric Random Access Memory (FRAM) device, etc., and/or a volatile memory device such as a Dynamic Random Access Memory (DRAM) device, a Static Random Access Memory (SRAM) device, a mobile DRAM device, etc.

The storage device 1030 may include a Solid State Drive (SSD), a Hard Disk Drive (HDD), a CD-ROM, etc. The input/output device 1040 may include input means such as a keyboard, a keypad, a touchpad, a touchscreen, a mouse, etc., and output means such as a speaker, a printer, etc. According to an embodiment, the display device 1060 may be included in the input/output device 1040. The power supply 1050 may supply power necessary for the operation of the electronic device 1000. The display device 1060 may be connected to other components through the buses or other communication links.

According to the display device according to the present invention described above, display quality of the display panel can be improved by reducing an afterimage of the display panel.

Although the present disclosure has been described with reference to exemplary embodiments, those skilled in the art will understand that various modifications and changes can be made to the present disclosure without departing from the spirit and scope of the present disclosure described in the following claims.

What is claimed is:

1. A display device comprising:
a metal layer;
a multi-functional layer disposed on the metal layer, the multi-functional layer comprising graphite and a resin mixed with the graphite;
an adhesive layer disposed on the multi-functional layer;
a display substrate disposed on the adhesive layer;
a printed circuit board; and
a conductive connector directly connecting a first surface of the printed circuit board and a lower surface of the metal layer.

2. The display device of claim 1, wherein a mass ratio of the graphite in the multi-functional layer is 30 wt % to 90 wt %, and a mass ratio of the resin in the multi-functional layer is 70 wt % to 10 wt %.

3. The display device of claim 1, wherein, in a cross-sectional view, a width of the multi-functional layer is equal to a width of the adhesive layer.

4. The display device of claim 1, wherein the multi-functional layer is an anisotropic heat dissipation member, and the metal layer is an isotropic heat dissipation member.

5. The display device of claim 4, wherein the multi-functional layer and the metal layer are in direct contact.

6. The display device of claim 1, further comprising:
a first anisotropic conductive film disposed on the display substrate;
a second anisotropic conductive film disposed on a second surface of the printed circuit board; and
a flexible film contacting the first anisotropic conductive film and the second anisotropic conductive film.

7. The display device of claim 6, further comprising:
a first driving circuit disposed on the flexible film; and
a second driving circuit disposed on the second surface of the printed circuit board.

8. The display device of claim 1, wherein, in a cross-sectional view, a width of the conductive connector is equal to a width of the printed circuit board.

9. The display device of claim 1, wherein, in a cross-sectional view, a width of the conductive connector is smaller than a width of the printed circuit board.

10. The display device of claim 9, wherein the conductive connector is integrally formed with the metal layer.

11. The display device of claim 9, wherein the conductive connector is a pin of the printed circuit board protruding from the printed circuit board.

12. The display device of claim 1, further comprising a metal electrode contacting the lower surface of the metal layer.

13. The display device of claim 12, wherein the metal electrode is connected to a ground.

14. The display device of claim 12, wherein the metal electrode is connected to a power voltage line of the display device.

15. The display device of claim 1, further comprising an insulating layer disposed between the multi-functional layer and the metal layer.

16. The display device of claim 1, further comprising a second display substrate disposed on the display substrate,
wherein, in a cross-sectional view, a width of the display substrate is greater than a width of the second display substrate.

17. The display device of claim 1, wherein the multi-functional layer comprises graphite powder of a first size and graphite powder of a second size smaller than the first size.

18. The display device of claim 17, wherein the graphite powder of the first size is 60 μm or more and 100 μm or less, and the graphite powder of the second size is 4 μm or more and 40 μm or less.

19. A display device comprising:
a metal layer;
a multi-functional layer contacting the metal layer, the multi-functional layer comprising graphite and a resin mixed with the graphite;
an adhesive layer disposed on the metal layer and the multi-functional layer; and
a display substrate disposed on the adhesive layer.

20. A display device comprising:
a metal layer;
a multi-functional layer contacting the metal layer, the multi-functional layer comprising a heat dissipation material comprising at least one of graphite, graphene, carbon fiber, carbon nanotube, boron nitride, and alumina, and a resin mixed with the heat dissipation material;
an adhesive layer disposed on the metal layer and the multi-functional layer; and
a display substrate disposed on the adhesive layer.
